(19) United States
(12) Patent Application Publication
(10) Pub. No.: US 2023/0154727 A1
(43) Pub. Date: May 18, 2023

(54) APPARATUS AND METHOD FOR PROCESSING SUBSTRATE

(71) Applicant: SEMES CO., LTD., Chungcheongnam-do (KR)

(72) Inventor: Jin Cheol PARK, Seoul (KR)

(21) Appl. No.: 17/879,782

(22) Filed: Aug. 3, 2022

(30) Foreign Application Priority Data
Nov. 16, 2021 (KR) 10-2021-0158067

(51) Int. Cl. H01J 37/32

(52) U.S. Cl. CPC H01J 37/3211; H01J 37/32183; H01J 37/32091; H01J 2237/334; H01J 37/32577

(57) ABSTRACT

Provided are an apparatus and method for processing a substrate, in which different types of plasmas are used simultaneously to complement each other's shortcomings and maximize their advantages. The apparatus for processing a substrate includes: a housing; a substrate support unit disposed inside the housing and configured to support a substrate; a shower head unit disposed inside the housing and configured to supply a process gas onto the substrate; an antenna unit disposed outside the housing; and a plasma generating unit configured to generate, inside the housing, a plasma for use in processing the substrate on the basis of the process gas, wherein the plasma generating unit generates both a first plasma and a second plasma using the antenna unit and the shower head unit as electrodes.

### CROSS-REFERENCE TO RELATED APPLICATION

This application claims priority from Korean Patent Application No. 10-2021-0158067 filed on Nov. 16, 2021, in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to an apparatus and method for processing a substrate. More particularly, the present disclosure relates to an apparatus and method for processing a substrate with a plasma.

### 2. Description of the Related Art

A semiconductor device fabrication process may be performed continuously in a semiconductor device fabrication facility, and may be classified into preprocessing and post-processing procedures. The semiconductor device fabrication facility may be installed in a space defined as a FAB to fabricate a semiconductor device.

The preprocessing procedure is a process of generating a chip by forming a circuit pattern on a wafer. The preprocessing procedure may include a deposition process of forming a thin film on a wafer, a photo lithography process of transferring a photoresist on the thin film using a photo mask, an etching process of selectively removing an unnecessary portion using a chemical material or a reactive gas to form a desired circuit pattern on the wafer, an ashing process for removing the photoresist remaining after the etching process, an ion implantation process of implanting ions into a portion connected to the circuit pattern to enable the portion to have characteristics of an electronic element, and a cleaning process of removing contaminates from the wafer.

The post-processing procedure is a process of evaluating the performance of the product fabricated through the preprocessing procedure. The post-processing procedure may include a primary test process of determining whether the chips are normal or defective by testing whether each chip on the wafer operates normally, a packaging process of cutting and separating each chip to form the product through dicing, die bonding, wire bonding, molding, marking, etc., and a final test process of finally testing characteristics and reliability of the product through an electrical characteristic test, a burn-in test, and the like.

### SUMMARY

When a substrate is processed with a plasma, any one type of plasma selected from capacitively coupled plasma (CCP) and inductively coupled plasma (ICP) may be used.

However, when the CCP is used, it is difficult to independently control ion energy and electron density. On the other hand, when the ICP is used, it is difficult to apply the plasma to a large-area substrate due to low uniformity of the plasma.

Aspects of the present disclosure provide an apparatus and method for processing a substrate, in which different types of plasmas are used simultaneously to complement each other's shortcomings and maximize the advantages thereof.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided an apparatus for processing a substrate including: a housing; a substrate support unit disposed inside the housing and configured to support a substrate; a shower head unit disposed inside the housing and configured to supply a process gas onto the substrate; an antenna unit disposed outside the housing; and a plasma generating unit configured to generate, inside the housing, a plasma for use in processing the substrate on the basis of the process gas, wherein the plasma generating unit generates both a first plasma and a second plasma using the antenna unit and the shower head unit as electrodes.

The plasma generating unit may simultaneously increase plasma density and plasma uniformity on the basis of an electric field formed on the substrate in a width direction of the substrate and an electric field formed on the substrate in a height direction of the substrate.

The plasma generating unit may simultaneously generate the first plasma and the second plasma, or sequentially generate the first plasma and the second plasma.

The antenna unit may be attached to an outer sidewall of the housing or an upper surface of the housing.

When the plasma generating unit uses the antenna unit as the electrode, the plasma generating unit may include: a high frequency power source configured to apply radio frequency (RF) power to the antenna unit; a transmission line configured to include a first line configured to connect a first terminal of the high frequency power source to a first point of the antenna unit and a second line configured to connect a second terminal of the high frequency power source to a second point of the antenna unit; an auxiliary line branching out from the transmission line and connected to a ground GND; and a matching module configured to match RF power on the first line and RF power on the second line.

The auxiliary line may branch out from the first line and the matching module may be installed on the second line.

The first plasma may be an inductively coupled plasma (ICP) and the second plasma may be a capacitively coupled plasma (CCP).

When the plasma generating unit sequentially generates the first plasma and the second plasma, the plasma generating unit may first generate the second plasma.

The plasma generating unit may further use the substrate support unit as the electrode when generating the first plasma and the second plasma.

When the antenna unit is attached to the outer sidewall of the housing, the antenna unit may have a cylindrical structure.

When the antenna unit is attached to the upper surface of the housing, the antenna unit may have a planar structure.

The high frequency power source may be provided in plural number, and a plurality of high frequency power sources may be connected in parallel to each of the first line and the second line.

When the antenna unit is attached to the outer sidewall of the housing, the antenna unit may have the same size as a height of the housing or may have a size to be smaller than the height of the housing.

When the antenna unit has a size smaller than the height of the housing, the size of the antenna unit may correspond to a size or location of a plasma region related to the generation of the plasma.

According to another aspect of the present disclosure, there is provided an apparatus for processing a substrate including: a housing; a substrate support unit disposed inside the housing and configured to support a substrate; a shower head unit disposed inside the housing and configured to supply a process gas onto the substrate; an antenna unit disposed outside the housing; and a plasma generating unit configured to generate, inside the housing, a plasma for use in processing the substrate on the basis of the process gas, wherein the plasma generating unit simultaneously generates a first plasma and a second plasma using the antenna unit, the shower head unit, and the substrate support unit as electrodes, the first plasma is an inductively coupled plasma (ICP), the second plasma is a capacitively coupled plasma (CCP), the antenna unit is attached to an outer sidewall of the housing, and the plasma generating unit simultaneously increases plasma density and plasma uniformity on the basis of an electric field formed on the substrate in a width direction of the substrate and an electric field formed on the substrate in a height direction of the substrate.

According to another aspect of the present disclosure, there is provided a method of processing a substrate including: disposing a substrate on a substrate support unit disposed in a housing; supplying a process gas onto the substrate by using a shower head unit disposed inside the housing; and generating, inside the housing, a plasma for use in processing the substrate on the basis of the process gas, wherein the generating of the plasma includes generating both a first plasma and a second plasma by using an antenna unit disposed outside the housing and the shower head unit as electrodes and simultaneously increasing plasma density and plasma uniformity on the basis of an electric field formed on the substrate in a width direction of the substrate and an electric field formed on the substrate in a height direction of the substrate.

The generating of the plasma may include simultaneously generating the first plasma and the second plasma, or sequentially generating the first plasma and the second plasma.

In the generating of the plasma, a unit attached to the outer sidewall of the housing or a unit attached to an upper surface of the housing may be used as the antenna unit.

The generating of the plasma may include generating the first plasma and the second plasma by further using the substrate support unit as the electrode.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a cross-sectional view illustrating an internal structure of an apparatus for processing a substrate according to a first embodiment of the present disclosure;

FIG. 2 is a cross-sectional view illustrating an internal structure of an apparatus for processing a substrate according to a second embodiment of the present disclosure;

FIG. 3 is a cross-sectional view illustrating an internal structure of an apparatus for processing a substrate according to a third embodiment of the present disclosure;

FIG. 4 is a first exemplary view for explaining an effect obtainable by using a plasma generating unit that constitutes the apparatus for processing a substrate according to the first embodiment of the present disclosure;

FIG. 5 is a first exemplary view for explaining an effect obtainable by using a plasma generating unit that constitutes the apparatus for processing a substrate according to the first embodiment of the present disclosure;

FIG. 6 is a cross-sectional view illustrating an internal structure of an apparatus for processing a substrate according to a fourth embodiment of the present disclosure;

FIG. 7 is a cross-sectional view illustrating an internal structure of an apparatus for processing a substrate according to a fifth embodiment of the present disclosure;

FIG. 8 is a first exemplary view for explaining an effect obtainable by using a plasma generating unit that constitutes the apparatus for processing a substrate according to the fifth embodiment of the present disclosure;

FIG. 9 is a second exemplary view for explaining an effect obtainable by using a plasma generating unit that constitutes the apparatus for processing a substrate according to the fifth embodiment of the present disclosure;

FIG. 10 is a first exemplary diagram for explaining another operation example of the apparatus for processing a substrate according to the first embodiment of the present disclosure; and

FIG. 11 is a second exemplary diagram for explaining another operation example of the apparatus for processing a substrate according to the first embodiment of the present disclosure.

### DETAILED DESCRIPTION OF THE EMBODIMENTS

Hereinafter, preferred embodiments of the present disclosure will be described in detail with reference to the accompanying drawings. Advantages and features of the present disclosure and methods of accomplishing the same may be understood more readily by reference to the following detailed description of preferred embodiments and the accompanying drawings. The present disclosure may, however, be embodied in different forms and should not be construed as limited to the embodiments set forth herein. Rather, these embodiments are provided so that this disclosure will be thorough and complete, and will filly convey the scope of the present disclosure to those skilled in the art. The same reference numbers indicate the same components throughout the specification.

It will also be understood that when a layer is referred to as being “on” another layer or substrate, it can be directly on the other layer or substrate, or intervening layers may also be present. In contrast, when an element is referred to as being “directly on” another element, there are no intervening elements present.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated components, steps, operations, and/or elements, but do not preclude the presence or addition of one or more other components, steps, operations, and/or elements.

Unless defined otherwise, all technical and scientific terms used herein have the same meaning as commonly understood by one of ordinary skill in the art to which this present disclosure belongs. Further, unless defined otherwise, all terms defined in generally used dictionaries may not be overly interpreted.

Hereinafter, exemplary embodiments of the present disclosure will be described in detail with reference to the accompanying drawings. In the description with reference to the drawings, the same or corresponding elements are denoted by the same reference numerals, and a redundant description thereof will be omitted.

The present disclosure relates to an apparatus and method for processing a substrate in which different types of plasma are used simultaneously to complement each other's shortcomings and maximize their advantages. The present disclosure relates to an apparatus and method for processing a substrate in which, for example, both a capacitively coupled plasma (CCP) source and an inductively coupled plasma (ICP) source are used simultaneously to complement each other's shortcomings and maximize their advantages.

When a substrate is processed using a CCP source, a plasma of uniform density can be generated and is suitable for processing a large-area substrate. However, the plasma density is low and it is difficult to independently control ion energy and electron density.

On the other hand, when a substrate is processed using an ICP source, the plasma density is high and independent control of ion energy and electron density is feasible, unlike the case in which the substrate is processed using the CCP source. However, the plasma uniformity is low and it is difficult to treat a large-area substrate.

In the present disclosure, an apparatus for processing a substrate is configured to simultaneously use different types of plasmas. That is, in the present disclosure, an apparatus for processing a substrate is configured to simultaneously use a CCP source and an ICP source. According to the present disclosure, it is possible to generate a plasma of uniform density, which is suitable for processing a large-area substrate, and to enable independent control of ion energy and electron density. The present disclosure will be described in detail with reference to the drawings and the like.

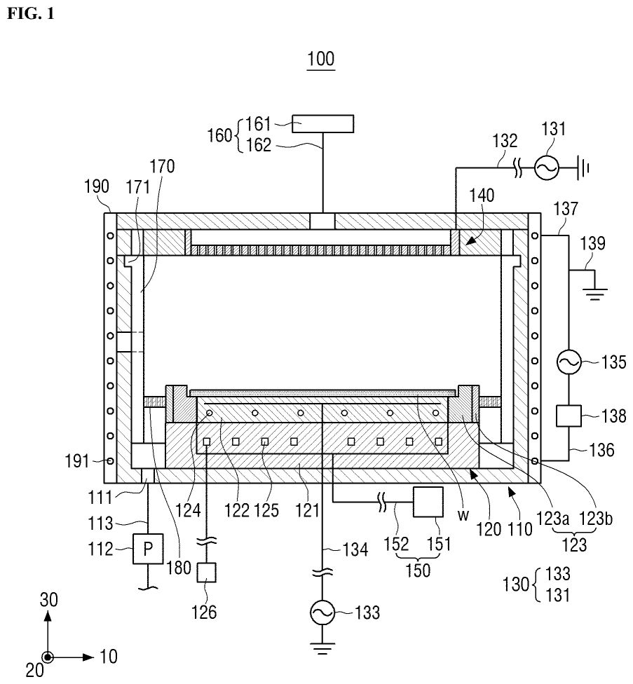

FIG. 1 is a cross-sectional view illustrating an internal structure of an apparatus for processing a substrate according to a first embodiment of the present disclosure.

Referring to FIG. 1, an apparatus 100 for processing a substrate may be configured to include a housing 110, a substrate support unit 120, a plasma generating unit 130, a shower head unit 140, a first gas supply unit 150, a second gas supply unit 160, a liner unit 170, a baffle unit 180, and an antenna unit 190.

The apparatus 100 for processing a substrate is an apparatus for processing a substrate W (e.g., wafer) using a plasma. The apparatus 100 for processing a substrate may perform an etching process or a cleaning process on the substrate W in a vacuum environment, and may perform a deposition process on the substrate W. The apparatus 100 may be provided as, for example, an etching process chamber, a cleaning process chamber, or a deposition process chamber.

The housing 110 provides a space in which a process of treating the substrate W with plasma, i.e., a plasma process, is performed. The housing 110 may be provided with an exhaust hole 111 at a lower portion thereof.

The exhaust hole 111 may be connected to an exhaust line 113 in which a pump 112 is installed. The exhaust hole 111 may discharge a by-product generated during the plasma process and a residual gas in the housing 110 to the outside of the housing 110 through the exhaust line 113. In this case, the interior space of the housing 110 may be depressurized to a predetermined pressure.

The housing 110 may have an opening 114 formed on a sidewall thereof. The opening 114 may function as a passage through which the substrate W enters and exits the housing 110. Although not illustrated in FIG. 1, the opening 114 may be configured to be opened and closed by a door assembly.

The door assembly may be configured to include an outer door a and a door driver. The outer door may be formed on the outer wall of the housing 110. The outer door a may move in the height direction of the apparatus 100, i.e., a third direction 30, by means of the door driver. The door driver may be driven by using at least one selected from a motor, a hydraulic cylinder, and a pneumatic cylinder.

The substrate support unit 120 may be mounted on a lower area inside the housing 110. The substrate support unit 120 may support the substrate W using an electrostatic force. However, the present embodiment is not limited thereto. The substrate support unit 120 may support the substrate W in various manners such as using mechanical clamping or vacuum.

In the case where the substrate support unit 120 supports the substrate W using the electrostatic force, the substrate support unit 120 may be configured to include a base 121 and an electrostatic chuck (ESC) 122.

The ESC 122 may support the substrate settled on the upper part thereof using the electrostatic force. The ESC 122 may be made of a ceramic material and fixedly connected onto the base 121.

Although not shown in FIG. 1, the ESC 122 may be mounted so as to move in the third direction 30 inside the housing 110 by means of a driving member. In the case where the ESC 122 is mounted so as to move in the height direction of the apparatus 100, it may be possible to locate the substrate W at a position at which the plasma distribution is more uniform.

A ring assembly 123 may be provided to surround the edge of the ESC 122. The ring assembly 123 has a ring shape and may be configured to support the edge region of the substrate W. The ring assembly 123 may be configured to include a focus ring 123a and an edge ring 123b.

The focus ring 123a may be arranged inside the edge ring 123b to directly surround the ESC 122. The focus ring 123a may be made of a silicon material and may serve to concentrate plasma on the substrate W during a plasma process in the housing 110.

The edge ring 123b may be arranged outside the focus ring 123a to surround the focus ring 123a. The edge ring 123b, which is an insulating ring, may be made of a quartz material and may serve to prevent the side surface of the ESC 122 from being damaged by plasma.

A heating member 124 and a cooling member 125 may be provided for the substrate W to maintain a process temperature during the etching process in the housing 110. The heating member 124 may be provided in the form of a heat line to increase the temperature of the substrate W, and may be installed inside the substrate support unit 120, for example, inside the ESC 122. The cooling member 125 may be provided in the form of a cooling line through which a refrigerant is flowing to lower the temperature of the substrate W and may be installed inside the substrate support unit 120, for example, inside the base 121.

Meanwhile, the cooling member 125 may be supplied with a coolant from a chiller 126. The chiller 126 may be installed outside the housing 110.

The first gas supply unit 150 may supply a first gas for removing foreign substances remaining on the ESC 122 or the ring assembly 123. For this purpose, the first gas supply unit 150 may include a first gas supply source 151 and a first gas supply line 152.

The first gas supply source 151 may supply nitrogen (N2) gas as the first gas. The first gas supply source 151 may supply a different gas or a cleansing agent, other than the nitrogen gas, as long as it can remove the foreign substances remaining on the ESC 122 or the ring assembly 123.

The first gas supply line 152 may deliver the first gas supplied from the first gas supply source 151. The first gas supply line 152 may be connected to a space between the ESC 122 and the focus ring 123a, and the first gas may remove the foreign substances remaining at the edge portion of the ESC 122 or on an upper portion of the ring assembly 123 through the space.

The plasma generating unit 130 may generate a plasma from the gas remaining in a discharge space. Here, the discharge space may mean a space located above the substrate support unit 120 in the interior space of the housing 110. The plasma generating unit 130 will be described in detail further below.

The shower head unit 140 may feed a process gas into the interior space of the housing 110. To this end, the shower head unit 140 may include a plurality of gas feeding holes.

The shower head unit 140 may be installed to face the ESC 122 in the up-down direction inside the housing 110. The shower head unit 140 may have a diameter greater than that of the ESC 133, or may have the same diameter as that of the ESC 122. The shower head unit 140 may be made of a silicon material or metal material.

The shower head unit 140 may be divided into a plurality of modules. For example, the shower head unit 140 may be divided into three modules, a first module, a second module, and a third module. In this case, the first module may supply a process gas to a center zone of the substrate W, and the second module may be arranged to surround the outside of the first module to supply the process gas to a middle zone of the substrate W. In addition, the third module may be arranged to surround the outside of the second module to supply the process gas to an edge zone of the substrate W.

The second gas supply unit 160 may supply a process gas (second gas) into the interior space of the housing 110 through the shower head unit 140. To this end, the second gas supply unit 160 may include a second gas supply source 121 and a second gas supply line 162.

The second gas supply source 161 may supply a process gas as a gas for use in treating the substrate W. The second gas supply source 161 may supply, for example, an etching gas or a cleaning gas as the process gas, and may supply a deposition gas as the process gas.

At least one second gas supply source 161 may be provided in the apparatus 100 for processing a substrate. When a plurality of second gas supply sources 161 are provided in the apparatus 100 for processing a substrate, it is possible to supply a large amount of gas within a short period of time. Also, when a plurality of second gas supply sources 161 are provided in the apparatus 100 for processing a substrate, the plurality of second gas supply sources 161 may each supply a different gas. For example, some second gas supply sources 161 may supply an etching gas, some other second supply sources 161 may supply a cleaning gas, and the other second supply sources 161 may supply a deposition gas.

The second gas supply line 162 may deliver the process gas supplied by the second gas supply source 161 to the shower head unit 140. For this purpose, the second gas supply line 162 may connect the second gas supply source 161 to the shower head unit 140, and in this case, it may be connected to the shower head unit 140 by penetrating the upper portion of the housing 110.

Although not shown in FIG. 1, when the shower head unit 140 is divided into a plurality of modules, the second gas supply unit 160 may further include a gas distributor and a gas distribution line for distributing the process gas to the respective modules of the shower head unit 140. The gas distributor may distribute the process gas being supplied from the second gas supply source 161 to the respective modules of the shower head unit 140. The gas distribution line may deliver the process gas distributed by the gas distributor to the respective modules of the shower head unit 140.

The liner unit (or wall liner) 170 may protect the inside of the housing 110 against arc discharge occurring during the excitation of the process gas and impurities being produced during the substrate processing process. To this end, the liner unit 170 may be configured to cover the inner sidewall of the housing 110.

The liner unit 170 may include a support ring 171 at an upper portion thereof. The support ring 171 may be formed to protrude outward (i.e., in a first direction 10) at the upper portion of the liner 170 and may serve to fix the liner unit 170 to the housing 110.

The baffle unit 180 may exhaust the by-product of the plasma, unreacted gas, or the like. The baffle unit 180 may be installed between the inner sidewall of the housing 110 and the support unit 120.

The baffle unit 180 may have a ring shape and may be provided with a plurality of penetration holes penetrating in the up-down direction (i.e., third direction 30). The baffle unit 180 may control the flow of the process gas according to the number and shape of the penetration holes.

The antenna unit 190 may produce a magnetic field and an electric field inside the housing 100 to excite the gas, which is flown into the inside of the housing 110 through the shower head unit 140, into a plasma. To this end, the antenna unit 190 may include an antenna 191 provided to form a close loop using a coil, and may use radio frequency (RF) power supplied from a third high frequency power source 135.

The antenna unit 190 may be installed along the periphery of the outer sidewall of the housing 110. In this case, the antenna 191 may be installed using the height direction of the housing 110 (third direction 30) as a longitudinal direction, and may have the same height as that of the housing 110. The antenna unit 190 may be detachably installed on the sidewall of the housing 110.

The plasma generating unit 130 may generate a plasma in a discharge space inside the housing 110 using a CCP source and an ICP source. That is, the plasma generating unit 130 may generate the plasma in the discharge space inside the housing 110 using the CCP source and the ICP source(?). In this case, the plasma generating unit 130 may use, for example, the shower head unit 140 as a first electrode, the ESC 122 as a second electrode, and the antenna unit 190 as a third electrode.

The plasma generating unit 130 may be configured to include a first high frequency power source 131, a first transmission line 132, a second transmission line 134, a first electrode, a second electrode, a second high frequency power source 135, a third transmission line 136, a fourth transmission line 137, a matching module 138, an auxiliary line 139, and a third electrode.

The first high frequency power source 131 may apply RF power to the first electrode. For example, when the shower head unit 140 is used as the first electrode, the first high frequency power source 131 may apply RF power to the shower head unit 140. However, the present embodiment is not limited thereto. The first electrode may be installed inside the housing 110 or separately installed outside the housing 110. In this case, the shower head unit 140 may not be used as the first electrode.

The first transmission line 132 may be connected to the first electrode and a ground GND. The first high frequency power source 131 may be installed on the first transmission line 132.

The second high frequency power source 133 may apply RF power to the second electrode. For example, when the ESC 122 is used as the second electrode, the second high frequency power source 133 may apply RF power to the ESC 122.

The second transmission line 134 may be connected to the second electrode and the ground GND. The second high frequency power source 133 may be installed on the second transmission line 134.

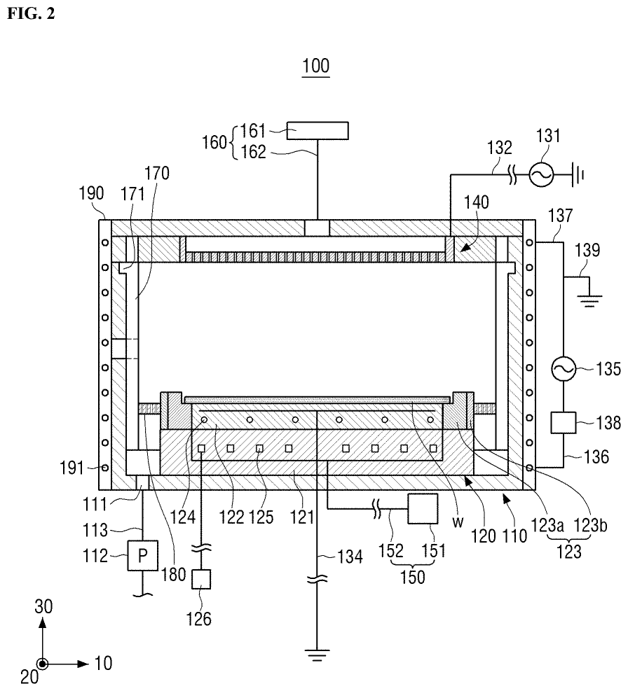

When the second high frequency power source 133 is installed on the second transmission line 134, the plasma generating unit 130 may be allowed to apply multi-frequency to the apparatus 100 for processing a substrate, and accordingly, the substrate processing efficiency of the apparatus 100 for processing a substrate may be improved. However, the present embodiment is not limited thereto. The plasma generating unit 130 may be configured to omit the second high frequency power source 133 as shown in FIG. 2. That is, the second high frequency power source 133 may not be installed on the second transmission line 134. FIG. 2 is a cross-sectional view illustrating an internal structure of an apparatus for processing a substrate according to a second embodiment of the present disclosure.

The following description will be made with reference back to FIG. 1.

The third high frequency power source 135 may apply RF power to the third electrode. For example, when the antenna unit 190 is used as the third electrode, the third high frequency power source 135 may apply RF power to the antenna unit 190.

The third transmission line 136 may connect the third high frequency power source 135 to a first point of the antenna unit 190, and the fourth transmission line 137 may connect the third high frequency power source 135 to a second point of the antenna unit 190. In the above description, an input terminal of the third high frequency power source 135 may be connected to the fourth transmission line 137, and an output terminal of the third high frequency power source 135 may be connected to the third transmission line 136. However, the present embodiment is not limited thereto. The input terminal of the third high frequency power source may be connected to the third transmission line 136, and the output terminal of the third high frequency power source 135 may be connected to the fourth transmission line 137.

When the RF power differs in magnitude between the input and output terminals of the third high frequency power source 135, the matching module 138 may match the RF powers and apply the same to the third electrode. That is, the matching module 138 may match the RF power on the third transmission line 136 and the RF power on the fourth transmission line 137. For the purpose, the matching module 138 may be installed on the third transmission line 136.

The auxiliary line 139 may be connected to one point on the fourth transmission line 137 and the ground GND. When the matching module 138 is installed on the third transmission line 136, the auxiliary line 139 may connect the one point on the fourth transmission line 137 and the ground GND. However, the present embodiment is not limited thereto. When the matching module 138 may be installed on the fourth transmission line 137, the auxiliary line 139 may connect one point on the third transmission line 136 and the ground GND.

In FIG. 1, the antenna unit 190 may be installed to surround the outer sidewall of the housing 110, and the third high frequency power source 135, the third transmission line 136, the fourth transmission line 137, the matching module 138, and the auxiliary line 139 may be installed to be connected to one side of the antenna unit 190.

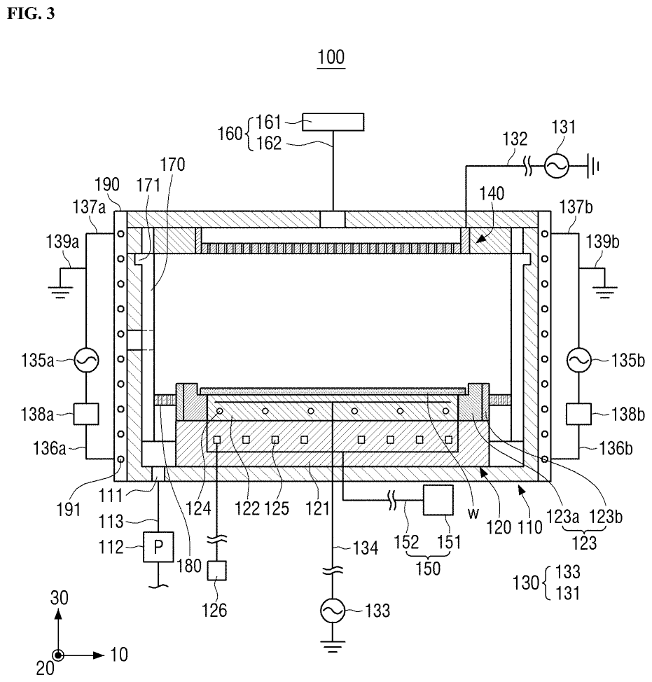

However, the present embodiment is not limited thereto. As shown in FIG. 3, third high frequency power sources 135a and 135b, third transmission lines 136a and 136b, fourth transmission lines 137a and 137b, matching modules 138a and 138b, and auxiliary lines 139a and 139b may be installed to be connected to both sides of the antenna unit 190.

Here, the third high frequency power source 135a, the third transmission line 136a, the fourth transmission line 137a, the matching module 138a, and the auxiliary line 139a which are installed on one side of the antenna unit 190 may face the third high frequency power source 135b, the third transmission line 136b, the fourth transmission line 137b, the matching module 138b, and the auxiliary line 139b which are installed on the other side of the antenna unit 190. When the two third high frequency power sources 135a and 135b are installed on both sides of the antenna unit 190, the same effect may be obtained as the case in which the first high frequency power source 131 and the second high frequency power source 133 are provided. FIG. 3 is a cross-sectional view illustrating an internal structure of an apparatus for processing a substrate according to a third embodiment of the present disclosure.

Meanwhile, an antenna unit 190 may be divided into two sections, wherein one section may be installed to surround a portion of the outer sidewall of a housing 110, and the other section may be installed to surround the remaining portion of the outer sidewall of the housing 110. In this case, third high frequency power sources 135a and 135b, third transmission lines 136a and 136b, fourth transmission lines 137a and 137b, matching modules 138a and 138b, and auxiliary lines 139a and 139b may be connected to the respective divided sections of the antenna unit 190.

In the above description, the first electrode, the second electrode, the third electrode, the first high frequency power source 131, the first transmission line 132, the second high frequency power source 133, the second transmission line 134, the third high frequency power source 135, the third transmission line 136, the fourth transmission line 137, the matching module 138, and the auxiliary line 139 that constitute the plasma generating unit 130 are described.

As described above, the plasma generating unit 130 may generate a plasma in a discharge space inside the housing 110 by using a CCP source and an ICP source. In this case, the plasma generating unit 130 may use the first electrode and the second electrode as the CCP source, and may use the third electrode and the second electrode as the ICP source.

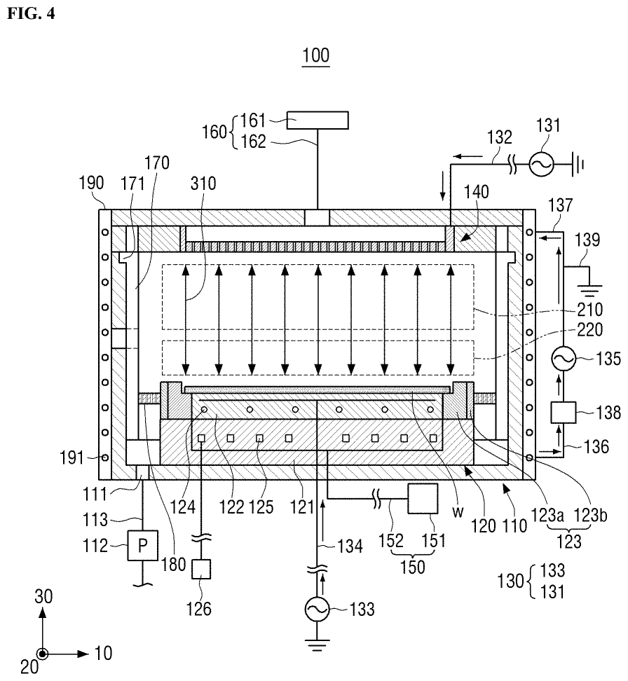

When the first electrode and the second electrode are used as the CCP source and the shower head unit 140 and the ESC 122 are used as the first electrode and the second electrode, respectively, a first electric field 310 may be produced in an up-down direction (third direction 30) in a plasma region 210 located between the shower head unit 140 and the ESC 122 as shown in FIG. 4. Accordingly, in this case, a plasma of uniform density may be generated in the plasma region 210 to increase plasma uniformity, and thus it is possible to treat a large-area substrate in a process region 220. FIG. 4 is a first exemplary view for explaining an effect obtainable by using a plasma generating unit that constitutes the apparatus for processing a substrate according to the first embodiment of the present disclosure.

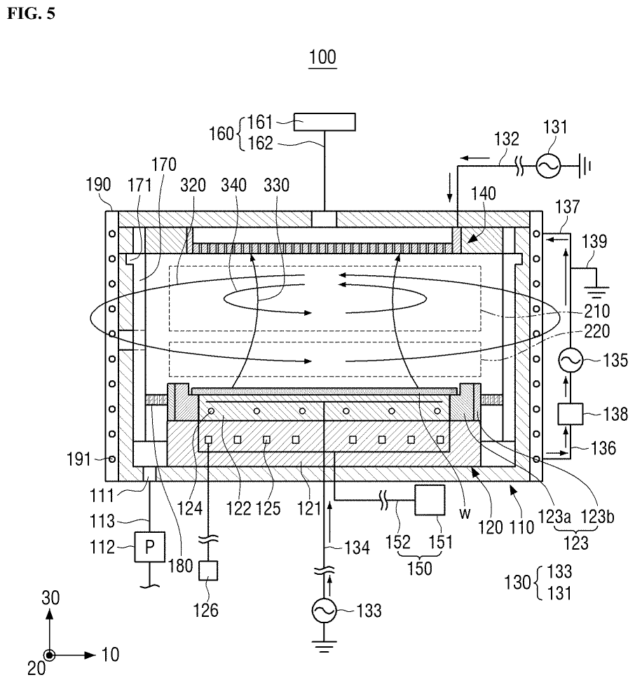

In addition, when the third electrode and the second electrode are used as the ICP source and the antenna unit 190 and the ESC 122 are used as the third electrode and the second electrode, respectively, a second electric field 230 may be produced along the periphery of the outer sidewall of the housing 110 by the antenna unit 190 and a magnetic field 330 may be produced in the up-down direction of the housing 110. Accordingly, as shown in FIG. 5, an induced electric field 340 may be produced in the left-right direction (the first direction 10 or the second direction 20) in the plasma region 210. Thus, in this case, plasma density may be increased in the plasma region 210, and accordingly, it is possible to independently control ion energy and electron density. FIG. 5 is a first exemplary view for explaining an effect obtainable by using a plasma generating unit that constitutes the apparatus for processing a substrate according to the first embodiment of the present disclosure.

In the present disclosure, the plasma generating unit 130 simultaneously uses the CCP source and the ICP source by using the first electrode, the second electrode, and the third electrode, thereby increasing the plasma uniformity and the plasma density, so that the independent control of ion energy and electron density and the processing of a large-area substrate can be achieved.

The following description will be made with reference back to FIG. 1.

A single first high frequency power source 131 may be provided inside the apparatus 100 for processing a substrate, but a plurality of first high frequency power sources 131 may be provided in the apparatus 100. When a plurality of first high frequency power sources 131 are provided inside the apparatus 100, the first high frequency power sources 131 may be arranged in parallel on the first transmission line 132.

In addition, when a plurality of first high frequency power sources 131 are provided inside the apparatus 100, although not shown in FIG. 1, the plasma generating unit 130 may further include a first matching network configured to be electrically connected to the plurality of first high frequency power sources 131. Here, when frequency powers of different magnitudes are input from the respective first high frequency power sources, the first matching network may serve to match the frequency powers and apply the same to the first electrode.

Meanwhile, although not shown in FIG. 1, a first impedance matching circuit may be provided for the purpose of impedance matching on the first transmission line 132 connecting the first high frequency power source 131 and the first electrode. The first impedance matching circuit may operate as a lossless passive circuit for maximally transferring the electric energy from the first high frequency power source 131 to the first electrode.

In the same manner as the first high frequency power source 131, a single second high frequency power source 133 may be provided inside the apparatus 100 for processing a substrate, and a plurality of second high frequency power sources may be provided inside the apparatus 100. When a plurality of second high frequency power sources 133 are provided inside the apparatus 100, the second high frequency power sources 133 may be arranged in parallel on the second transmission line 134.

In addition, when a plurality of second high frequency power sources 133 are provided inside the apparatus 100, although not shown in FIG. 1, the plasma generating unit 130 may further include a second matching network configured to be electrically connected to the plurality of second high frequency power sources 133. Here, when frequency powers of different magnitudes are input from the respective second high frequency power sources, the second matching network may serve to match the frequency powers and apply the same to the second electrode.

Meanwhile, although not shown in FIG. 1, a second impedance matching circuit may be provided for the purpose of impedance matching on the second transmission line 134 connecting the second high frequency power source 133 and the second electrode. The second impedance matching circuit may operate as a lossless passive circuit for maximally transferring the electric energy from the second high frequency power source 133 to the second electrode.

Meanwhile, a single third high frequency power source 135 may be provided inside the apparatus 100 for processing a substrate, and a plurality of third high frequency power sources 135 may be provided inside the apparatus 100. When a plurality of third high frequency power sources 135 are provided inside the apparatus 100, the third high frequency power sources 135 may be arranged in parallel on each of the third transmission line 136 and the fourth transmission line 137.

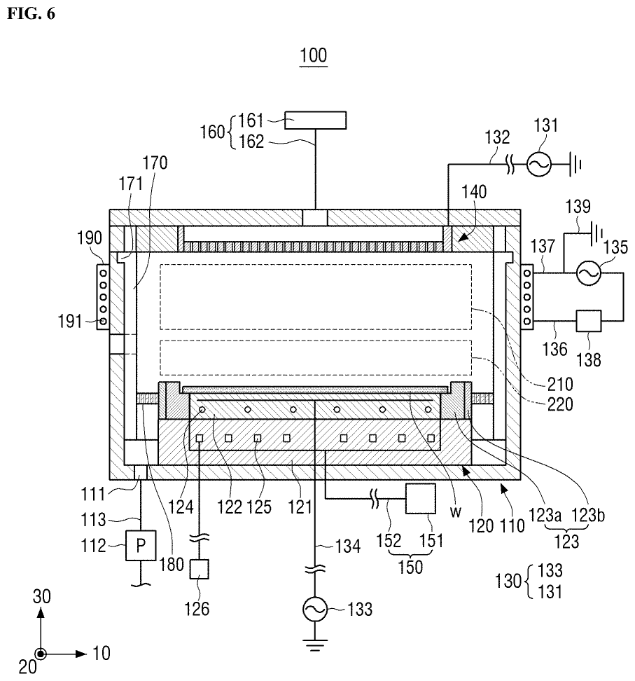

As described above, the antenna unit 190 may be installed along the periphery of the outer sidewall of the housing 110 (third direction 30), and may have the same height as that of the housing 110. However, the present embodiment is not limited thereto. The antenna unit 190 may be provided in suitable size in consideration of the size of the plasma region 210 as shown in FIG. 6. That is, the antenna unit 190 may be installed along the periphery of the outer sidewall of the housing 110, and may have a size smaller than the height of the housing 110. FIG. 6 is a cross-sectional view illustrating an internal structure of an apparatus for processing a substrate according to a fourth embodiment of the present disclosure.

In the apparatus 100 for processing a substrate described above with reference to FIGS. 1 to 6, the antenna unit 190 may be of a cylindrical type. However, the present embodiment is not limited thereto. The antenna unit 190 may be of a planar type, and the apparatus 100 for processing a substrate may use the planar-type antenna unit 190 as the third electrode, which will be described in detail below.

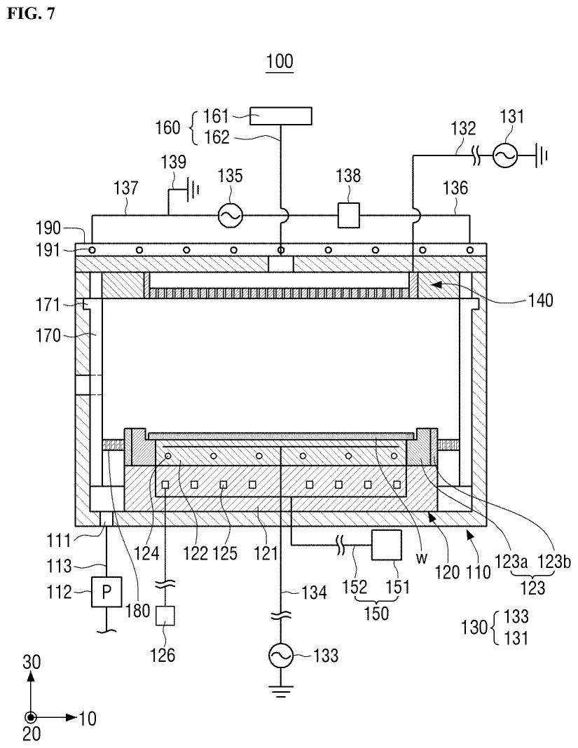

FIG. 7 is a cross-sectional view illustrating an internal structure of an apparatus for processing a substrate according to a fifth embodiment of the present disclosure.

In the same manner as the apparatus 100 for processing a substrate shown in FIG. 1, an apparatus 100 for processing a substrate shown in FIG. 7 may be configured to include a housing 110, a substrate support unit 120, a plasma generating unit 130, a shower head unit 140, a first gas supply unit 150, a second gas supply unit 160, a liner unit 170, a baffle unit 180, and an antenna unit 190.

The respective units 110 to 190 included in the apparatus 100 of FIG. 7 may function the same as the respective units 110 to 190 included in the apparatus 100 of FIG. 1. Thus, detailed descriptions of the respective units 110 to 190 included in the apparatus 100 of FIG. 7 will be omitted. Only differences between the units 110 to 190 included in the apparatus 100 of FIG. 7 and the units 110 to 190 included in the apparatus 100 of FIG. 1 will be described below.

In the apparatus 100 of FIG. 1, the antenna unit 190 may be attached to surround the outer sidewall of the housing 110. On the contrary, in the apparatus 100 of FIG. 7, the antenna unit 190 may be attached onto an upper surface of the housing 110. In this case, the antenna 191 may be installed using the width direction of the housing 110 (first direction 10) as a longitudinal direction, and may have a size corresponding to the diameter of the housing 110.

Meanwhile, although not shown in FIG. 7, a window module may be installed between the upper surface of the housing 110 and the antenna unit 190. In this case, the upper surface of the housing 110 may be open, and the window module may be installed to cover the upper surface of the housing 110. That is, the window module may serve as an upper cover of the housing 110 to seal the interior space of the housing 110.

The window module may be formed as a dielectric window made of an insulating material (e.g., alumina (Al₂O₃)). The window module may be configured to include a coating layer on a surface thereof to prevent particles from being generated while a plasma process is performed inside the housing 110, and a through-hole may be formed through which the second gas supply line 162 is inserted.

Meanwhile, although not shown in FIG. 7, the upper surface of the housing 110 may be opened, and the antenna unit 190 may be installed to function as an upper cover of the housing 110.

As described above, the plasma generating unit 130 may produce a plasma in a discharge space inside the housing 110 by using the CCP source and the ICP source, and may use the shower head unit 140 as the first electrode, the ESC 122 as the second electrode, and the antenna unit 190 as the third electrode. In this case, the plasma generating unit 130 may use the first electrode and the second electrode as the CCP source, and may use the third electrode and the second electrode as the ICP source.

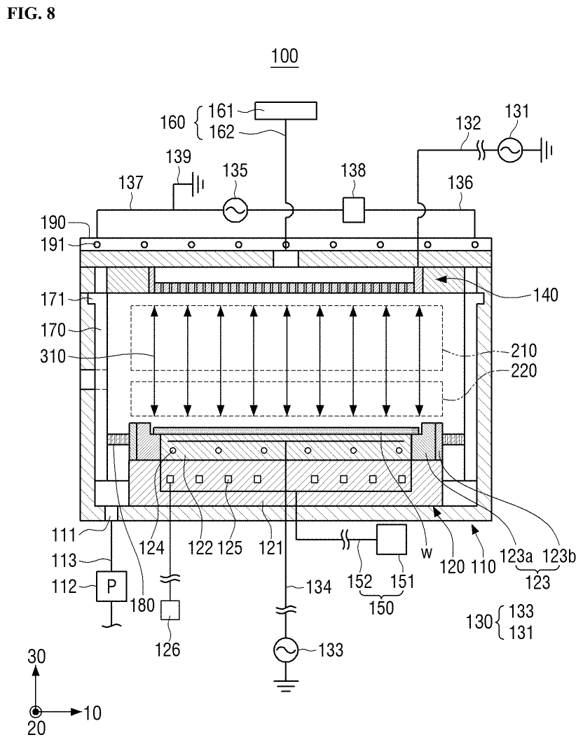

When the first electrode and the second electrode are used as the CCP source and the shower head unit 140 and the ESC 122 are used as the first electrode and the second electrode, respectively, a first electric field 310 may be produced in an up-down direction (third direction 30) in the plasma region 210 located between the shower head unit 140 and the ESC 122 as shown in FIG. 8. Accordingly, in this case, a plasma of uniform density may be generated in the plasma region 210 to increase plasma uniformity, and thus it is possible to treat a large-area substrate in the process region 220. FIG. 8 is a first exemplary view for explaining an effect obtainable by using a plasma generating unit that constitutes the apparatus for processing a substrate according to the fifth embodiment of the present disclosure.

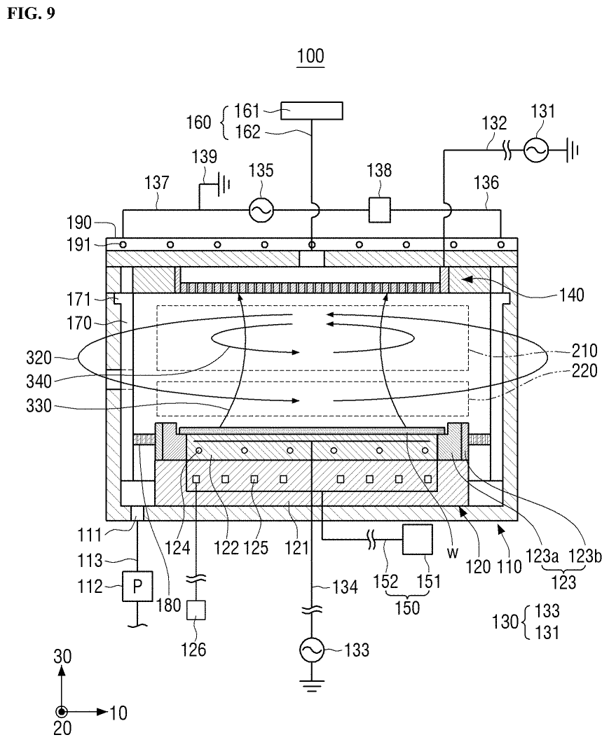

In addition, when the third electrode and the second electrode are used as the ICP source and the antenna unit 190 and the ESC 122 are used as the third electrode and the second electrode, respectively, a second electric field 230 may be produced on the antenna unit 190, and a magnetic field 330 may be produced in the up-down direction of the housing 110. Accordingly, as shown in FIG. 9, an induced electric field 340 may be produced in the left-right direction (the first direction 10 or the second direction 20) in the plasma region 210. Thus, in this case, plasma density may be increased in the plasma region 210, and accordingly, it is possible to independently control ion energy and electron density. FIG. 9 is a second exemplary view for explaining an effect obtainable by using a plasma generating unit that constitutes the apparatus for processing a substrate according to the fifth embodiment of the present disclosure.

In the present disclosure, the plasma generating unit 130 simultaneously uses the CCP source and the ICP source by using the first electrode, the second electrode, and the third electrode, thereby increasing the plasma uniformity and the plasma density, so that the independent control of ion energy and electron density and the processing of a large-area substrate can be achieved.

In the above description, the apparatus 100 for processing a substrate which is capable of simultaneously using the CCP source and the ICP source is described with reference to FIGS. 1 to 9. Specifically, the apparatus 100 for processing a substrate which includes the cylindrical type antenna unit 190 is described with reference to FIGS. 1 to 6, and the apparatus 100 for processing a substrate which includes the planar type antenna unit 190 is described with reference to FIGS. 7 to 9.

In the present disclosure, the apparatus 100 for processing a substrate may operate both the CCP source and the ICP source when treating a substrate W. In this case, the CCP source and the ICP source may be simultaneously operated, but the present embodiment is not necessarily limited thereto. That is, the CCP source and the ICP source may be sequentially operated.

When the CCP source and the ICP source are sequentially operated, the CCP source may be first operated and then the ICP source may be operated in order to increase both the plasma uniformity and the plasma density and thus achieve both the independent control of ion energy and electron density and the processing of a large-area substrate. In this case, the ICP source may serve to increase activation of the plasma generated from the CCP source.

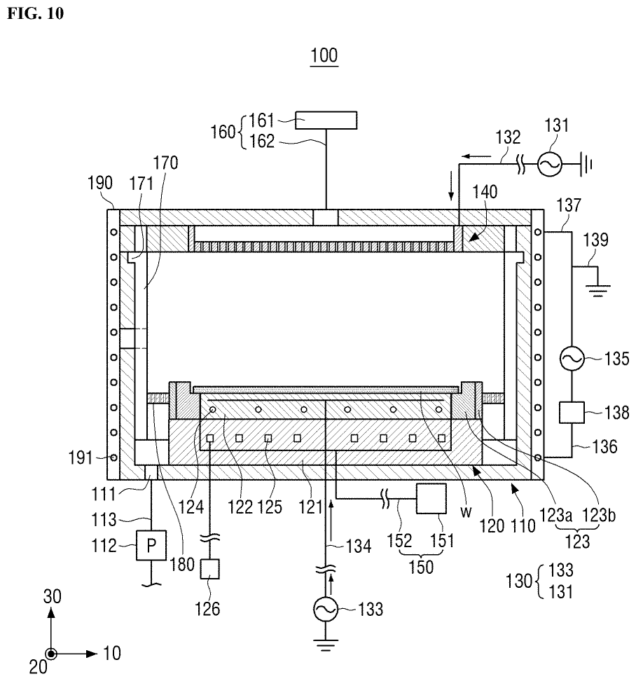

Meanwhile, in the present disclosure, only one of the CCP source and the ICP source may be operated without operating both the CCP source and the ICP source. For example, when a silicon compound (e.g., silicon oxide) is etched, only the CCP source may be operated as shown in FIG. 10. FIG. 10 is a first exemplary diagram for explaining another operation example of the apparatus for processing a substrate according to the first embodiment of the present disclosure.

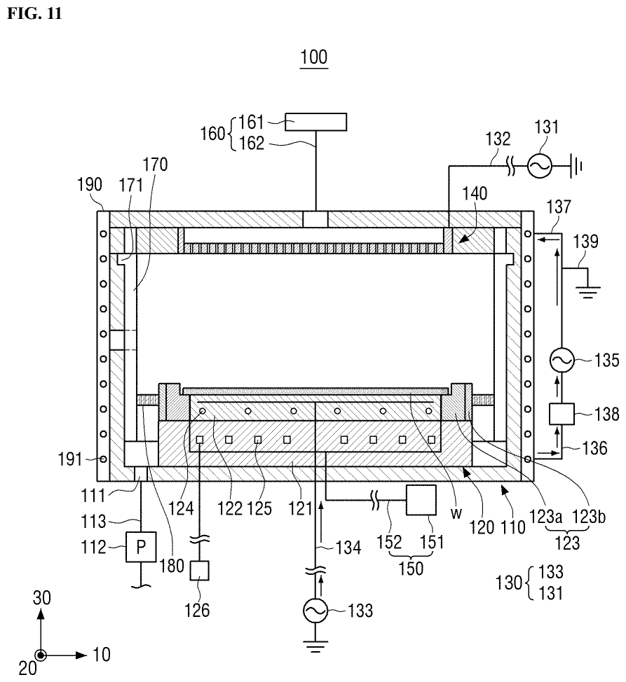

For example, when poly silicon is etched or a thin film is deposited on the substrate W, only the ICP source may be operated as shown in FIG. 11. FIG. 11 is a second exemplary diagram for explaining another operation example of the apparatus for processing a substrate according to the first embodiment of the present disclosure.

Equipment used for an etching process in the semiconductor fabrication process may perform the etching process using either type of plasma, CCP or ICP. In the case of CCP, a plasma of uniform density can be produced and thus is applicable to a large-area wafer. However, a plasma of a relatively low density is produced and it is difficult to independently control ion energy and electron density.

On the other hand, in the case of ICP, a plasma of a relatively high density is produced and the independent control of plasma density and ion energy is feasible. Thus, an increase of an etching rate and a low-pressure process can be achieved according to an increase in the plasma density and the straightness of ions can be secured by the increase in a mean free path (MFP), which makes the ICP suitable for use in a next-generation high aspect ratio (HAR) process. However, the ICP has a low plasma density and thus is difficult to apply to a large-area wafer.

According to the present disclosure, two types of plasmas, i.e., CCP and ICP, may be used simultaneously to complement each other's shortcomings and maximize their advantages. Further, according to the present disclosure, it is possible to provide an apparatus 100 for processing a substrate that is optimized for a next-generation HAR process.

While various embodiments have been described, those skilled in the art will appreciate that many variations and modifications can be made to the preferred embodiments without substantially departing from the principles of the present disclosure. Therefore, the disclosed preferred embodiments of the present disclosure are used in a generic and descriptive sense only and not for purposes of limitation.

What is claimed:

1. An apparatus for processing a substrate, comprising:
a housing;
a substrate support unit disposed inside the housing and configured to support a substrate;
a shower head unit disposed inside the housing and configured to supply a process gas onto the substrate;
an antenna unit disposed outside the housing; and
a plasma generating unit configured to generate, inside the housing, a plasma for use in processing the substrate on the basis of the process gas,
wherein the plasma generating unit generates both a first plasma and a second plasma using the antenna unit and the shower head unit as electrodes.

2. The apparatus of claim 1, wherein the plasma generating unit is configured to simultaneously increase plasma density and plasma uniformity on the basis of an electric field formed on the substrate in a width direction of the substrate and an electric field formed on the substrate in a height direction of the substrate.

3. The apparatus of claim 1, wherein the plasma generating unit is configured to simultaneously generate the first plasma and the second plasma, or sequentially generate the first plasma and the second plasma.

4. The apparatus of claim 1, wherein the antenna unit is attached to an outer sidewall of the housing or an upper surface of the housing.

5. The apparatus of claim 1, wherein, when the plasma generating unit uses the antenna unit as the electrode, the plasma generating unit comprises: a high frequency power source configured to apply radio frequency (RF) power to the antenna unit; a transmission line configured to include a first line configured to connect a first terminal of the high frequency power source to a first point of the antenna unit and a second line configured to connect a second terminal of the high frequency power source to a second point of the antenna unit; an auxiliary line branching out from the transmission line and connected to a ground GND; and a matching module configured to match RF power on the first line and RF power on the second line.

6. The apparatus of claim 5, wherein the auxiliary line branches out from the first line and the matching module may be installed on the second line.

7. The apparatus of claim 1, wherein the first plasma is an inductively coupled plasma (ICP) and the second plasma is a capacitively coupled plasma (CCP).

8. The apparatus of claim 7, wherein, when the plasma generating unit sequentially generates the first plasma and the second plasma, the plasma generating unit first generates the second plasma.

9. The apparatus of claim 1, wherein the plasma generating unit further uses the substrate support unit as the electrode when generating the first plasma and the second plasma.

10. The apparatus of claim 4, wherein, when the antenna unit is attached to the outer sidewall of the housing, the antenna unit has a cylindrical structure.

11. The apparatus of claim 4, wherein, when the antenna unit is attached to the upper surface of the housing, the antenna unit has a planar structure.

12. The apparatus of claim 5, wherein the high frequency power source is provided in plural number and a plurality of high frequency power sources are connected in parallel to each of the first line and the second line.

13. The apparatus of claim 4, wherein, when the antenna unit is attached to the outer sidewall of the housing, the antenna unit has the same size as a height of the housing or has a size to be smaller than the height of the housing.

14. The apparatus of claim 13, wherein, when the antenna unit has a size smaller than the height of the housing, the size of the antenna unit corresponds to a size or location of a plasma region related to the generation of the plasma.

15. An apparatus for processing a substrate, comprising:
a housing;
a substrate support unit disposed inside the housing and configured to support a substrate;
a shower head unit disposed inside the housing and configured to supply a process gas onto the substrate;
an antenna unit disposed outside the housing; and
a plasma generating unit configured to generate, inside the housing, a plasma for use in processing the substrate on the basis of the process gas, wherein:
the plasma generating unit simultaneously generates a first plasma and a second plasma using the antenna unit, the shower head unit, and the substrate support unit as electrodes,
the first plasma is an inductively coupled plasma (ICP), the second plasma is a capacitively coupled plasma (CCP),
the antenna unit is attached to an outer sidewall of the housing, and
the plasma generating unit simultaneously increases plasma density and plasma uniformity on the basis of an electric field formed on the substrate in a width direction of the substrate and an electric field formed on the substrate in a height direction of the substrate.

16. A method of processing a substrate, comprising:
disposing a substrate on a substrate support unit disposed in a housing;
supplying a process gas onto the substrate by using a shower head unit disposed inside the housing; and
generating, inside the housing, a plasma for use in processing the substrate on the basis of the process gas,
wherein the generating of the plasma comprises generating both a first plasma and a second plasma by using an antenna unit disposed outside the housing and the shower head unit as electrodes and simultaneously increasing plasma density and plasma uniformity on the basis of an electric field formed on the substrate in a width direction of the substrate and an electric field formed on the substrate in a height direction of the substrate.

17. The method of claim 16, wherein the generating of the plasma comprises simultaneously generating the first plasma and the second plasma, or sequentially generating the first plasma and the second plasma.

18. The method of claim 16, wherein, in the generating of the plasma, a unit attached to the outer sidewall of the housing or a unit attached to an upper surface of the housing is used as the antenna unit.

19. The method of claim 16, wherein the first plasma is an inductively coupled plasma (ICP) and the second plasma is a capacitively coupled plasma (CCP).

20. The method of claim 16, wherein the generating of the plasma comprises generating the first plasma and the second plasma by further using the substrate support unit as the electrode.
